(19) United States
(12) Patent Application Publication
(10) Pub. No.: US 2016/0042772 A1
(43) Pub. Date: Feb. 11, 2016

(54) SEMICONDUCTOR DEVICES

(71) Applicant: SK hynix, Icheon-si (KR)

(72) Inventors: Joon Woo CHOI, Busan (KR); Chang Ki BAEK, Anyang-si (KR)

(21) Appl. No.: 14/526,932

(22) Filed: Oct. 29, 2014

(30) Foreign Application Priority Data
Aug. 6, 2014 (KR) 10-2014-0101320

(51) Int. Cl. G11C 7/10; G11C 7/22

(52) U.S. Cl. CPC G11C 7/106; G11C 7/1057; G11C 7/222

(57) ABSTRACT

A semiconductor device may include a first input/output unit and a second input/output unit. The first input/output unit may operate in synchronization with an internal clock signal to output a first data as a first output data in response to a control signal or to output a transfer data generated from a second data as the first output data in response to the control signal. The second input/output unit may operate in synchronization with the internal clock signal to generate the transfer data while in a test mode. The first output data may be transmitted to a first pad.

### CROSS-REFERENCE TO RELATED APPLICATION

The present application claims priority under 35 U.S.C 119(a) to Korean Application No. 10-2014-0101320, filed on Aug. 6, 2014, in the Korean Intellectual Property Office, which is incorporated herein by reference in its entirety as set forth in full.

### BACKGROUND

1. Technical Field

Embodiments of the present disclosure relate to semiconductor devices.

2. Related Art

Semiconductor devices may execute a read operation to output stored data. Semiconductor devices may execute a write operation to input external data therein. The read operation may be performed to transmit data stored in memory banks to an external device through input/output (I/O) lines, internal circuits connected to the I/O lines, and data pads. The write operation may be performed to store external data into the memory banks through the data pads, the internal circuits, and the I/O lines connected to the internal circuits. That is, the data may be transmitted through the internal circuits electrically connected to the data pads during the read operation or the write operation.

In order to test whether the internal circuits of the semiconductor device are normally operating, the semiconductor device may execute the write operation and the read operation to input and output the data through the data pads. Then to verify the function of the internal circuits of the semiconductor device, the data outputted through the data pads may be evaluated.

However, as the semiconductor devices such as semiconductor memory devices become more highly integrated, the testing times needed to verify a normality or abnormality of the internal circuits have increased as a result of the higher integrations.

### SUMMARY

According to an embodiment, a semiconductor device may include a first input/output unit and a second input/output unit. The first input/output unit may operate in synchronization with an internal clock signal to output a first data as a first output data in response to a control signal or to output a transfer data generated from a second data as the first output data in response to the control signal. The second input/output unit may operate in synchronization with the internal clock signal to generate the transfer data while in a test mode. The first output data may be transmitted to a first pad.

According to an embodiment, a semiconductor device may include a first input/output unit and a second input/output unit. The first input/output unit may operate in synchronization with an internal clock signal to output a first data as a first output data in response to a control signal or may operate in synchronization with the internal clock signal and compares the first data with a transfer data generated from a second data to generate the first output data in response to the control signal. The second input/output unit may operate in synchronization with the internal clock signal to generate the transfer data while in a test mode and to output the second data as a second output data while not in the test mode. The first output data may be transmitted to a first pad, and the second output data may be transmitted to a second pad.

According to an embodiment, a semiconductor device may include a first input/output unit suitable for latching a first data to output the latched first data as a first internal data, a second input/output unit suitable for latching a second data to output the latched second data as a second internal data, and a data transfer unit suitable for operating in synchronization with an internal clock signal to output the first internal data or the second internal data as a first output data in response to a control signal. The first output data may be transmitted to a first pad.

According to an embodiment, a semiconductor device may include a first input/output unit suitable for latching a first data to output the latched first data as a first internal data, a second input/output unit suitable for latching a second data to output the latched second data as a second internal data, and a data transfer unit suitable for operating in synchronization with an internal clock signal to output the first internal data as a first output data in response to a control signal or suitable for operating in synchronization with the internal clock signal and comparing the first internal data with the second internal data to generate the first output data in response to the control signal. The first output data may be transmitted to a first pad.

### BRIEF DESCRIPTION OF THE DRAWINGS

FIG. 1 is a block diagram illustrating a representation of a semiconductor device according to an embodiment.

FIG. 2 is a block diagram illustrating a representation of a first input/output unit included in the semiconductor device of FIG. 1.

FIG. 3 is a block diagram illustrating a representation of a second input/output unit included in the semiconductor device of FIG. 1.

FIG. 4 is a block diagram illustrating a representation of a first input/output unit with which the first input/output unit illustrated in FIG. 2 can be replaced.

FIG. 5 is a block diagram illustrating a representation of a semiconductor device according to an embodiment.

FIG. 6 illustrates a block diagram of an example of a representation of a system employing the semiconductor devices in accordance with the embodiments discussed above with relation to FIGS. 1-5.

### DETAILED DESCRIPTION OF THE EMBODIMENTS

Embodiments of the present disclosure will be described hereinafter with reference to the accompanying drawings. However, the embodiments described herein are for illustrative purposes only and are not intended to limit the scope of the present disclosure.

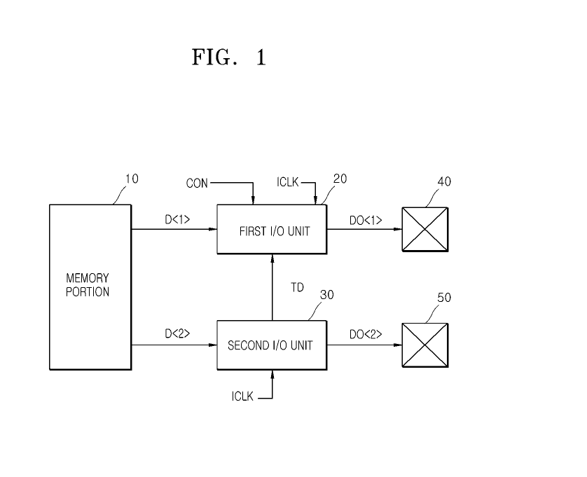

Referring to FIG. 1, a semiconductor device according to an embodiment may include a memory portion 10, a first input/output (I/O) unit 20, and a second I/O unit 30. The semiconductor device according to an embodiment may also include a first pad 40 and a second pad 50.

The memory portion 10 may include a plurality of memory cells and may generate a first data D<1> and a second data D<2> during a read operation. In a test mode, the first and second data D<1> and D<2> outputted from the memory portion 10 during the read operation may have the same logic level.

If a control signal CON is at a predetermined logic level (i.e., disabled), the first I/O unit 20 may operate in synchronization with an internal clock signal ICLK to output the first data D<1> as a first output data DO<1>. If the control signal CON is at a predetermined logic level (i.e., enabled), the first I/O unit 20 may operate in synchronization with the internal clock signal ICLK to output a transfer data TD generated from the second data D<2> as the first output data DO<1>. The first output data DO<1>, whether generated from the first data D<1> or from the transfer data TD generated from the second data D<2>, may be transmitted to an external device through the first pad 40. The control signal CON may be enabled in the test mode, and the internal clock signal ICLK may synchronize the semiconductor device with an external device to output the data stored in the semiconductor device or to input external data into the semiconductor device.

When the semiconductor device is in the test mode, the second I/O unit 30 may operate in synchronization with the internal clock signal ICLK to generate the transfer data TD in response to the second data D<2>. When the semiconductor device is not in the test mode or not operating in the test mode, the second I/O unit 30 may operate in synchronization with the internal clock signal ICLK to output the second data D<2> as a second output data DO<2>. The second output data DO<2> may be transmitted to an external device through the second pad 50.

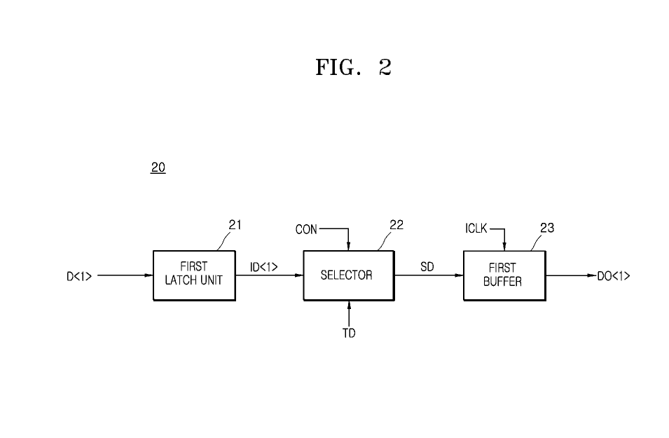

Referring to FIG. 2, the first I/O unit 20 may include a first latch unit 21, a selector 22 and a first buffer 23.

The first latch unit 21 may latch the first data D<1> and may output the latched first data D<1> as a first internal data ID<1>.

The selector 22 may output the first internal data ID<1> as a selection data SD if the control signal CON is disabled to have a logic “low” level. If the control signal CON is enabled to have a logic “high” level, the selector 22 may output the transfer data TD as the selection data SD.

The first buffer 23 may buffer the selection data SD in synchronization with the internal clock signal ICLK to generate the first output data DO<1>. The first output data DO<1> may be outputted through the first pad 40 (See FIG. 1).

If the first latch unit 21, the selector 22 and the first buffer 23 included in the first I/O unit 20 are operating normally, the first output data DO<1> outputted through the first pad 40 may be generated to have a logic “high” level. However, a logic level of the first output data DO<1> may be set to be different according to the various embodiments.

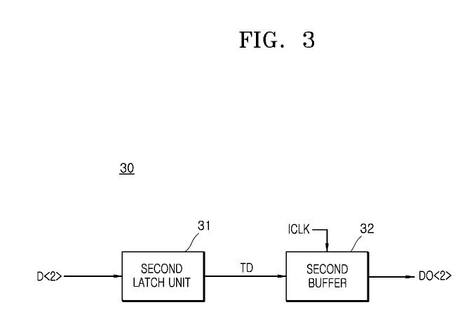

Referring to FIG. 3, the second I/O unit 30 may include a second latch unit 31 and a second buffer 32.

The second latch unit 31 may latch the second data D<2> and may output the latched second data D<2> as the transfer data TD.

When the semiconductor device is out of the test mode, the second buffer 32 may operate in synchronization with the internal clock signal ICLK to output the transfer data TD as the second output data DO<2>. The second output data DO<2> may be transmitted to an external device through the second pad 50 (See FIG. 1). In the test mode, the second buffer 32 may be disabled not to generate the second output data DO<2>. If the second latch unit 31 is operating normally, the transfer data TD may be generated to have a logic “high” level. However, a logic level of the transfer data TD may be set to be different according to the various embodiments.

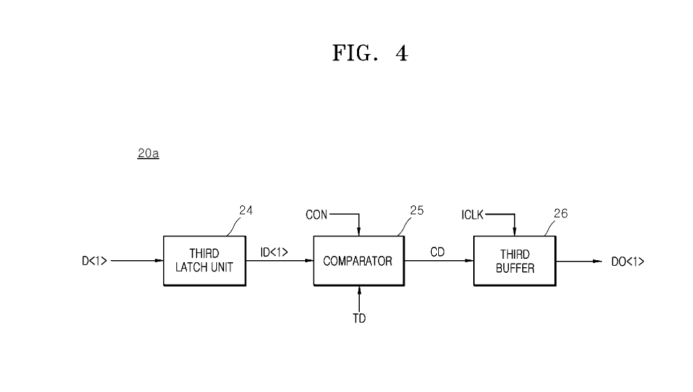

FIG. 4 is a block diagram illustrating a representation of a first I/O unit 20a with which the first I/O unit 20 illustrated in FIGS. 1 and 2 can be replaced.

Referring to FIG. 4, the first I/O unit 20a may include a third latch unit 24, a comparator 25 and a third buffer 26.

The third latch unit 24 may latch the first data D<1> and may output the latched first data D<1> as the first internal data ID<1>.

If the control signal CON is disabled to have a logic “low” level, the comparator 25 may output the first internal data ID<1> as a comparison data CD. If the control signal CON is enabled to have a logic “high” level the comparator 25 may compare the first internal data ID<1> with the transfer data TD to generate the comparison data CD.

The third buffer 26 may operate in synchronization with the internal clock signal ICLK to output the comparison data CD as the first output data DO<1>. The first output data DO<1> may be outputted through the first pad 40 (See FIG. 1).

If the third latch unit 24, the comparator 25 and the third buffer 26 included in the first I/O unit 20a are operating normally, then the first output data DO<1> outputted through the first pad 40 may be generated to have a logic “high” level. However, a logic level of the first output data DO<1> may be set to be different according to the various embodiments.

As described above, the first I/O unit 20a may operate in synchronization with the internal clock signal ICLK to output the first data D<1> as the first output data DO<1> if the control signal CON is disabled to have a logic “low” level. In addition, the first I/O unit 20a may operate in synchronization with the internal clock signal ICLK and may compare the first data D<1> with the transfer data TD to generate the first output data DO<1> if the control signal CON is disabled to have a logic “low” level. The first output data DO<1> may be outputted through the first pad 40 (See FIG. 1).

An operation of the semiconductor devices having the aforementioned configurations will be described hereinafter with reference to FIGS. 1 to 4 in conjunction with examples in which the first I/O unit 20 outputs the first data D<1> or the transfer data TD through the first pad 40 and other examples in which the first I/O unit 20a compares the first data D<1> with the transfer data TD to output the first output data DO<1> to the first pad 40.

First, when the semiconductor device is out of the test mode, an operation whereby the first I/O unit 20 may output the first data D<1> to the first pad 40 will be described hereinafter.

The memory portion 10 may execute the read operation to generate the first and second data D<1> and D<2> having a logic “high” level.

The first latch unit 21 of the first I/O unit 20 may latch the first data D<1> having a logic “high” level and may output the latched first data D<1> as the first internal data ID<1>.

The second latch unit 31 of the second I/O unit 30 may latch the second data D<2> having a logic “high” level and may output the latched second data D<2> as the transfer data TD.

The selector 22 of the first I/O unit 20 may output the first internal data ID<1> having a logic “high” level as the selection data SD because the control signal CON is disabled to have a logic “low” level.

The first buffer 23 of the first I/O unit 20 may operate in synchronization with the internal clock signal ICLK and may buffer the selection data SD to generate the first output data DO<1> having a logic “high” level. The first output data DO<1> having a logic “high” level may be transmitted to an external device through the first pad 40.

The second buffer 32 of the second I/O unit 30 may operate in synchronization with the internal clock signal ICLK to output the transfer data TD having a logic “high” level as the second output data DO<2>. The second output data DO<2> having a logic “high” level may be transmitted to an external device through the second pad 50.

Next, while the semiconductor device is in the test mode, an operation whereby the first I/O unit 20 may output the transfer data TD to the first pad 40 will be described hereinafter.

The memory portion 10 may execute the read operation to generate the first and second data D<1> and D<2> having a logic “high” level.

The first latch unit 21 of the first I/O unit 20 may latch the first data D<1> having a logic “high” level and may output the latched first data D<1> as the first internal data ID<1>.

The second latch unit 31 of the second I/O unit 30 may latch the second data D<2> having a logic “high” level and may output the latched second data D<2> as the transfer data TD.

The selector 22 of the first I/O unit 20 may output the transfer data TD having a logic “high” level as the selection data SD because the control signal CON is enabled to have a logic “high” level.

The first buffer 23 of the first I/O unit 20 may operate in synchronization with the internal clock signal ICLK and may buffer the selection data SD having a logic “high” level to generate the first output data DO<1> having a logic “high” level. The first output data DO<1> having a logic “high” level may be transmitted to an external device through the first pad 40.

The second buffer 32 of the second I/O unit 30 may be disabled not to generate the second output data DO<2>.

Next, while the semiconductor device is in the test mode, an operation whereby the first I/O unit 20a may compare the first data D<1> with the transfer data TD to output the first output data DO<1> to the first pad 40 will be described hereinafter.

The memory portion 10 may execute the read operation to generate the first and second data D<1> and D<2> having a logic “high” level.

The third latch unit 24 of the first I/O unit 20a may latch the first data D<1> having a logic “high” level and may output the latched first data D<1> as the first internal data ID<1>.

The second latch unit 31 of the second I/O unit 30 may latch the second data D<2> having a logic “high” level and may output the latched second data D<2> as the transfer data TD.

The comparator 25 of the first I/O unit 20a may compare the first internal data ID<1> having a logic “high” level with the transfer data TD having a logic “high” level to generate the comparison data CD because the control signal CON is enabled to have a logic “high” level. The comparator 25 may generate the comparison data CD having a logic “high” level because the first internal data ID<1> and the transfer data TD have the same logic level.

The third buffer 26 of the first I/O unit 20a may operate in synchronization with the internal clock signal ICLK to output the comparison data CD having a logic “high” level as the first output data DO<1>. The first output data DO<1> having a logic “high” level may be transmitted to an external device through the first pad 40.

The second buffer 32 of the second I/O unit 30 may be disabled not to generate the second output data DO<2>.

As described above, the internal circuits of the first and second I/O units 20 and 30 may be tested by verifying a logic level of the first output data DO<1> outputted through the first pad 40 which may be used as a common pad. Accordingly, a test time of the semiconductor device may be reduced.

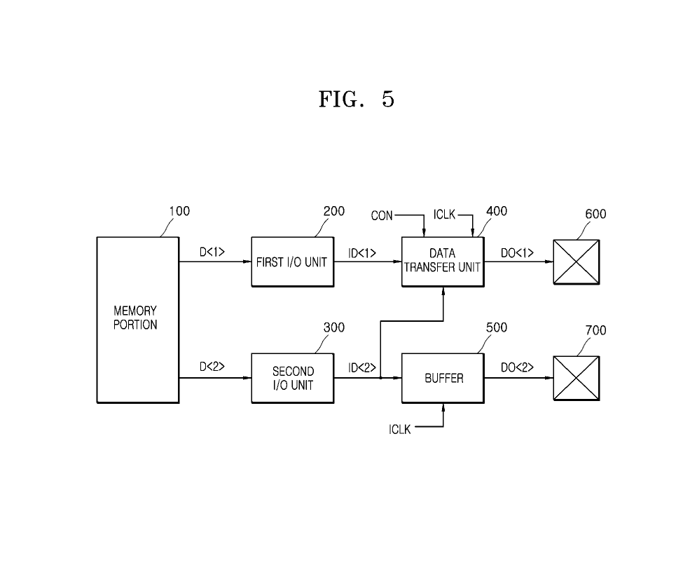

FIG. 5 is a block diagram illustrating a representation of a semiconductor device according to an embodiment of the present disclosure.

Referring to FIG. 5, the semiconductor device according to an embodiment may include a memory portion 100, a first I/O unit 200, a second I/O unit 300, and a data transfer unit 400. The semiconductor device may also include a buffer 500, a first pad 600, and a second pad 700.

The memory portion 100 may include a plurality of memory cells. The memory portion 100 may generate a first data D<1> and a second data D<2> during a read operation. In a test mode, the first and second data D<1> and D<2> outputted from the memory portion 100 during the read operation may have the same logic level.

The first I/O unit 200 may latch the first data D<1> and may output the latched first data D<1> as a first internal data ID<1>.

The second I/O unit 300 may latch the second data D<2> and may output the latched second data D<2> as a second internal data ID<2>.

If a control signal CON is disabled, the data transfer unit 400 may operate in synchronization with an internal clock signal ICLK to output the first internal data ID<1> as a first output data DO<1>. If the control signal CON is enabled, the data transfer unit 400 may operate in synchronization with the internal clock signal ICLK to output the second internal data ID<2> as the first output data DO<1>. The first output data DO<1>, whether generated from the first internal data ID<1> or from the second internal data ID<2>, may be transmitted to an external device through the first pad 600.

As a result, the data transfer unit 400 may operate in synchronization with an internal clock signal ICLK to output the first internal data ID<1> as a first output data DO<1> if the control signal CON is disabled. The data transfer unit 400 may operate in synchronization with an internal clock signal ICLK and may compare the first internal data ID<1> with the second internal data ID<2> to generate the first output data DO<1> if the control signal CON is enabled. The first output data DO<1> may be transmitted to an external device through the first pad 600. Moreover, if the first I/O unit 200, the data transfer unit 400 and the second I/O unit 300 are operating normally, then the first output data DO<1> outputted through the first pad 600 may be generated to have a logic “high” level. However, a logic level of the first output data DO<1> may be set to be different according to the various embodiments.

When the semiconductor device is not operating in the test mode, the buffer 500 may output the second internal data ID<2> as a second output data DO<2> and the second output data DO<2> may be transmitted to an external device through the second pad 700. In the test mode, the buffer 500 may be disabled not to generate the second output data DO<2>. If the second I/O unit 300 and the buffer 500 are operating normally when not operating in the test mode, then the second output data DO<2> outputted through the second pad 700 may be generated to have a logic “high” level. However, a logic level of the second output data DO<2> may be set to be different according to the various embodiments.

Hereinafter, an operation of the semiconductor device illustrated in FIG. 5 will be described in conjunction with an example in which the data transfer unit 400 outputs the first or second internal data ID<1> or ID<2> through the first pad 600 and an example in which the data transfer unit 400 compares the first internal data ID<1> with the second internal data ID<2> to output the first output data DO<1> to the first pad 600.

First, when the semiconductor device is not operating in the test mode, an operation whereby the data transfer unit 400 outputs the first internal data ID<1> through the first pad 600 will be described hereinafter.

The memory portion 100 may execute the read operation to generate the first and second data D<1> and D<2> having a logic “high” level.

The first I/O unit 200 may latch the first data D<1> having a logic “high” level and may output the latched first data D<1> as the first internal data ID<1>.

The second I/O unit 300 may latch the second data D<2> having a logic “high” level and may output the latched second data D<2> as the second internal data ID<2>.

The data transfer unit 400 may operate in synchronization with the internal clock signal ICLK to output the first internal data ID<1> having a logic “high” level as the first output data DO<1> because the control signal CON is disabled to have a logic “low” level. The first output data DO<1> having a logic “high” level may be transmitted to an external device through the first pad 600.

The buffer 500 may operate in synchronization with the internal clock signal ICLK to output the second internal data ID<2> having a logic “high” level as the second output data DO<2>. The second output data DO<2> having a logic “high” level may be transmitted to an external device through the second pad 700.

Next, while the semiconductor device is in the test mode, an operation whereby the data transfer unit 400 may output the second internal data ID<2> to the first pad 600 will be described hereinafter.

The memory portion 100 may execute the read operation to generate the first and second data D<1> and D<2> having a logic “high” level.

The first I/O unit 200 may latch the first data D<1> having a logic “high” level and may output the latched first data D<1> as the first internal data ID<1>.

The second I/O unit 300 may latch the second data D<2> having a logic “high” level and may output the latched second data D<2> as the second internal data ID<2>.

The data transfer unit 400 may operate in synchronization with the internal clock signal ICLK to output the second internal data ID<2> having a logic “high” level as the first output data DO<1> because the control signal CON is enabled to have a logic “high” level. The first output data DO<1> having a logic “high” level may be transmitted to an external device through the first pad 600.

The buffer 500 may be disabled not to generate the second output data DO<2>.

Next, while the semiconductor device is in the test mode, an operation whereby the data transfer unit 400 may compare the first internal data ID<1> with the second internal data ID<2> to output the first output data DO<1> through the first pad 600 will be described hereinafter.

The memory portion 100 may execute the read operation to generate the first and second data D<1> and D<2> having a logic “high” level.

The first I/O unit 200 may latch the first data D<1> having a logic “high” level and may output the latched first data D<1> as the first internal data ID<1>.

The second I/O unit 300 may latch the second data D<2> having a logic “high” level and may output the latched second data D<2> as the second internal data ID<2>.

The data transfer unit 400 may operate in synchronization with the internal clock signal ICLK and may compare the first internal data ID<1> having a logic “high” level with the second internal data ID<2> having a logic “high” level to generate the first output data DO<1> because the control signal CON is enabled to have a logic “high” level. The data transfer unit 400 may generate the first output data DO<1> having a logic “high” level because the first internal data ID<1> and the second internal data ID<2> have the same logic level. The first output data DO<1> having a logic “high” level may be transmitted to an external device through the first pad 600.

The buffer 500 may be disabled not to generate the second output data DO<2>.

As described above, the first and second I/O units 200 and 300 may be tested by verifying a logic level of the first output data DO<1> outputted through the first pad 600. The first pad 600 may be used as a common pad. Accordingly, a test time of the semiconductor device may be reduced.

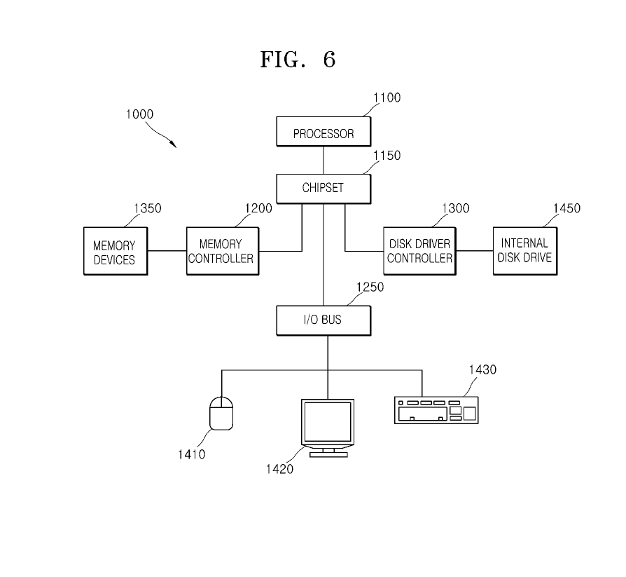

The semiconductor devices discussed above (see FIGS. 1-5) are particular useful in the design of memory devices, processors, and computer systems. For example, referring to FIG. 6, a block diagram of a system employing the semiconductor devices in accordance with the embodiments are illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150. The memory controller 1200 may include at least one semiconductor device as discussed above with reference to FIGS. 1-5. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor device as discussed above with relation to FIGS. 1-5, the memory devices 1350 may include a plurality of word lines and a plurality of bit lines for defining a plurality of memory cell. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 6 is merely one example of a system employing the semiconductor devices as discussed above with relation to FIGS. 1-5. In alternate embodiments, such as cellular phones or digital cameras, the components may differ from the embodiments illustrated in FIG. 6.

What is claimed is:

1. A semiconductor device comprising:
a first input/output unit suitable for operating in synchronization with an internal clock signal to output a first data as a first output data in response to a control signal or to output a transfer data generated from a second data as the first output data in response to the control signal; and
a second input/output unit suitable for operating in synchronization with the internal clock signal to generate the transfer data while in a test mode,
wherein the first output data is transmitted to a first pad.

2. The semiconductor device of claim 1, wherein the second input/output unit is suitable to output the second data as a second output data while not in the test mode.

3. The semiconductor device of claim 2, wherein the second output data is transmitted to a second pad.

4. The semiconductor device of claim 1, wherein the control signal is enabled in the test mode.

5. The semiconductor device of claim 1, wherein the first input/output unit includes:
a first latch unit suitable for latching the first data to generate a first internal data;
a selector suitable for outputting the transfer data as a selection data if the control signal is at a first predetermined logic level and suitable for outputting the first internal data as the selection data if the control signal is at a second predetermined logic level; and
a first buffer suitable for outputting the selection data as the first output data in synchronization with the internal clock signal.

6. The semiconductor device of claim 3, wherein the second input/output unit includes:
a second latch unit suitable for latching the second data to generate the transfer data; and
a second buffer suitable for operating in synchronization with the internal clock signal to output the transfer data as the second output data while not in the test mode.

7. The semiconductor device of claim 1, further comprising a memory portion suitable for outputting the first data and the second data,
wherein the memory portion includes a plurality of memory cells.

8. A semiconductor device comprising:
a first input/output unit suitable for operating in synchronization with an internal clock signal to output a first data as a first output data in response to a control signal or suitable for operating in synchronization with the internal clock signal and comparing the first data with a transfer data generated from a second data to generate the first output data in response to the control signal; and
a second input/output unit suitable for operating in synchronization with the internal clock signal to generate the transfer data while in a test mode and to output the second data as a second output data while not in the test mode,
wherein the first output data is transmitted to a first pad and the second output data is transmitted to a second pad.

9. The semiconductor device of claim 8, wherein the control signal is enabled in the test mode.

10. The semiconductor device of claim 8, wherein the first input/output unit includes:
a first latch unit suitable for latching the first data to generate a first internal data;
a comparator suitable for comparing the first internal data with the transfer data to generate a comparison data if the control signal is enabled and suitable for outputting the first internal data as the comparison data if the control signal is disabled; and
a first buffer suitable for operating in synchronization with the internal clock signal to buffer the comparison data and to output the buffered comparison data as the first output data.

11. The semiconductor device of claim 8, wherein the second input/output unit includes:
a second latch unit suitable for latching the second data to generate the transfer data; and
a second buffer suitable for operating in synchronization with the internal clock signal to output the transfer data as the second output data while not in the test mode.

12. The semiconductor device of claim 8, further comprising a memory portion suitable for outputting the first data and the second data,
wherein the memory portion includes a plurality of memory cells.

13. A semiconductor device comprising:
a first input/output unit suitable for latching a first data to output the latched first data as a first internal data;
a second input/output unit suitable for latching a second data to output the latched second data as a second internal data; and
a data transfer unit suitable for operating in synchronization with an internal clock signal to output the first internal data or the second internal data as a first output data in response to a control signal,
wherein the first output data is transmitted to a first pad.

14. The semiconductor device of claim 13, wherein the control signal is enabled in a test mode.

15. The semiconductor device of claim 13, further comprising:
a memory portion including a plurality of memory cells and outputting the first data and the second data; and
a buffer suitable for operating in synchronization with the internal clock signal to output the second internal data as a second output data,
wherein the second output data is transmitted to a second pad.

16. A semiconductor device comprising:
a first input/output unit suitable for latching a first data to output the latched first data as a first internal data;
a second input/output unit suitable for latching a second data to output the latched second data as a second internal data; and
a data transfer unit suitable for operating in synchronization with an internal clock signal to output the first internal data as a first output data in response to a control signal or suitable for operating in synchronization with the internal clock signal and comparing the first internal data with the second internal data to generate the first output data in response to the control signal,
wherein the first output data is transmitted to a first pad.

17. The semiconductor device of claim 16, wherein the control signal is enabled in a test mode.

18. The semiconductor device of claim 16, further comprising:
a memory portion including a plurality of memory cells and outputting the first data and the second data; and
a buffer suitable for operating in synchronization with the internal clock signal to output the second internal data as a second output data,
wherein the second output data is transmitted to a second pad.

19. A semiconductor device comprising:
a memory portion coupled to a first pad, and
a second pad coupled to the memory portion,
wherein the semiconductor device, while not in a test mode, is configured for outputting first data through the first pad,
wherein the semiconductor device, while in the test mode, is configured for outputting transfer data generated from second data through the first pad, and
wherein the semiconductor device is configured for outputting the second data through the second pad while not in the test mode.

20. The semiconductor device of claim 19, further comprising:
a first input/output unit coupled between the memory portion and the first and second pads, and configured for operating in synchronization with an internal clock signal to output the first data to the first pad while not in the test mode and for outputting the transfer data to the first pad while in the test mode.

21. The semiconductor device of claim 20, further comprising:
a second input/output unit coupled between the memory portion, the first input/output unit, and second pads, and configured for operating in synchronization with the internal clock signal to generate the transfer data while in the test mode.

22. The semiconductor device of claim 21, wherein the second input/output unit is configured for operating in synchronization with the internal clock signal to output the second data to the second pad while not in the test mode.

23. The semiconductor device of claim 22, wherein the memory portion includes a plurality of memory cells and is configured for outputting the first data to the first input/output unit and for outputting the second data to the second input/output unit.
